(19) United States
(12) Patent Application Publication
(10) Pub. No.: US 2013/0291935 A1
(43) Pub. Date: Nov. 7, 2013

(54) OPTICAL ANTI-REFLECTION STRUCTURE AND SOLAR CELL INCLUDING THE SAME, AND METHOD FOR MAKING THE OPTICAL ANTI-REFLECTION STRUCTURE

(71) Applicant: AU OPTRONICS CORPORATION, Hsin-chu (TW)

(72) Inventors: Po-Chuan YANG, HSIN-CHU (TW); I-Min CHAN, HSIN-CHU (TW)

(73) Assignee: AU OPTRONICS CORPORATION, HSIN-CHU (TW)

(21) Appl. No.: 13/723,462

(22) Filed: Dec. 21, 2012

(30) Foreign Application Priority Data
May 4, 2012 (CN) 201210137760.8

(51) Int. Cl. G02B 1/11; H01L 31/0232; H01L 31/0216

(52) U.S. Cl. CPC G02B 1/11; H01L 31/0216; H01L 31/02327
USPC 136/256; 359/601; 438/72

(57) ABSTRACT

Disclosed herein is an optical anti-reflective structure. The antireflective structure comprises a concave-convex surface structure and a nanoscale columnar structure on the surface of the concave-convex surface structure. Furthermore, a structure of a solar cell having the antireflective structure and a method of making the above antireflective structure are also provided.

### CROSS-REFERENCE TO RELATED APPLICATION

This application claims the priority benefit of China application serial no. 201210137760.8, filed May 4, 2012, the full disclosure of which is incorporated herein by reference.

### FIELD OF THE INVENTION

The present disclosure relates to an optical anti-reflection structure. More particularly, the present invention relates to an optical anti-reflection structure of multilayer nanoscale structure.

### BACKGROUND OF THE INVENTION

It has been nearly 60 years since the production of a solar cell with doping impurities into silicon by the Bell Laboratory. Nowadays solar cells have been widely used in our daily life. Solar cells currently in the market are mainly made of crystalline silicon; among which a monocrystalline silicon solar cell has the highest photoelectric conversion efficiency because of its fewer crystalline defects and lower electron-hole recombination.

The photoelectric conversion efficiency of the solar cell produced by crystalline silicon is about 18%. Nevertheless, silicon has the sunlight reflectivity up to 37.5%, and the high reflectivity is one of important factors that causes such low photoelectric conversion efficiency of the crystalline silicon solar cell. Except for the solar cell, there still exist needs to reduce surface reflectivity for other technical applications. To reduce reflectivity, coating an anti-reflection film on the surface of the solar cell and surface roughening are often used, but they still fail to achieve a satisfactory antireflection effect.

In view of the foregoing, there is a need for a technique that can reduce the surface reflectivity (e.g., issue of reducing sunlight reflection) to overcome the known problem of high reflectivity, and further solve the problem of lower energy conversion efficiency of the solar cell.

### SUMMARY OF THE INVENTION

The following presents a summary of the disclosure in order to provide a basic understanding to the reader. This summary is not an extensive overview of the disclosure and it does not identify key/critical elements of the present disclosure or delineate the scope of the present disclosure. Its sole purpose is to present some concepts disclosed herein in a simplified form as a prelude to the more detailed description that is presented later.

An aspect of the present disclosure provides an optical anti-reflection structure. The optical anti-reflection structure comprises a concave-convex surface structure, and a nanoscale columnar structure on the at least one portion of the concave-convex surface structure. According to one embodiment of the disclosure, the ratio of the average peak-valley distance of the concave-convex surface structure and the height of the nanoscale columnar structure is 10 to 100. The nanoscale columnar structure has a plurality of nanoscale columns with a height/diameter ratio of 10 to 100. The diameter of the nanoscale columns is in the range of 20 to 50 nanometers (nm).

According to another embodiment of the disclosure, the concave-convex surface structure is selected from the group consisting of a pyramid structure, a strip groove structure, an irregularly coarsening structure and combinations thereof.

According to another embodiment of the disclosure, the above pyramid structure is selected from a group consisting of an upright pyramid structure, an inverted pyramid structure, a flat-topped pyramid structure and combinations thereof.

According to yet another embodiment of the disclosure, the pyramid structure comprises a plurality of pyramid groups with different sizes. The pyramid groups with different sizes comprise a first pyramid group having a base width of 3 to 5 micrometers (μm), a second pyramid group having a base width of 5 to 8 μm, and a third pyramid group having a base width of 8 to 10 μm.

An aspect of the present disclosure provides a solar cell. The solar cell comprises a photoelectric conversion layer, a first electrode and a second electrode. The photoelectric conversion layer has a first surface and a second surface opposite to the first surface, and the first surface has an anti-reflection structure as the above-mentioned. The first electrode is disposed on the first surface, and the second electrode is disposed under the second surface opposite to the first electrode.

Another aspect of the present disclosure provides a method for making an anti-reflection structure, and steps comprise the following. First, a concave-convex surface is formed on a silicon substrate surface by an etching process, and a nanoscale columnar structure is formed on the concave-convex surface by a metal-assisted etching process for forming the anti-reflection structure, then a semiconductor layer is formed within the anti-reflection structure.

According to one embodiment of the disclosure, the step of forming the concave-convex surface is an isotropic etching process or an anisotropic etching process. The isotropic etching process comprises the step of soaking the silicon substrate in an acid solution for forming the concave-convex surface on the surface of the silicon substrate. The anisotropic etching process comprises the step of soaking the silicon substrate in an alkali solution for forming the concave-convex surface on the surface of the silicon substrate.

According to one embodiment of the disclosure, the step of forming the nanoscale columnar structure is a metal-assist etching process. The metal-assisted etching process comprises the step of performing oxidation on the silicon substrate by metal ions to produce silica.

According to another embodiment of the disclosure, the step of forming the semiconductor layer is a diffusion process or a deposition process. The diffusion process comprises the step of doping a plurality of group VA-elements into the anti-reflection structure to form an N-type semiconductor layer, or doping a plurality of group IIIA-elements into the anti-reflection structure to form a P-type semiconductor layer. The deposition method the step of depositing an N-type semiconductor material on the anti-reflection structure for forming the N-type semiconductor layer, or depositing a P-type semiconductor material on the anti-reflection structure for forming the P-type semiconductor layer.

According to yet another embodiment of the disclosure. The group VA-elements are phosphorous (P), arsenic (As) or antimony (Sb), and the group IIIV-elements are boron (B), aluminum (Al), gallium (Ga) or indium (In).

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 is a flow chart of a method for making an optical anti-reflection structure according to one embodiment of this disclosure;

FIG. 2A to 2C respectively illustrate the process steps of making the optical anti-reflection structure according to one embodiment of this disclosure;

FIG. 3A to 3E are cross-sectional views illustrating process steps of making method according to one embodiment of this disclosure;

FIG. 4A to 4B are scanning electron microscope images of an optical anti-reflection structure according to one embodiment of this disclosure;

FIG. 5A to 5F are schematic diagrams illustrating the concave-convex surface structure of an optical anti-reflection structure according to one embodiment of this disclosure;

FIG. 6 is a graph of reflectivity of optical anti-reflection structures at different wavelengths;

FIG. 7 is a graph of quantum conversion efficiency of solar cells at different wavelengths; and

FIG. 8 is a cross-sectional view of a solar cell according to one embodiment of this disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

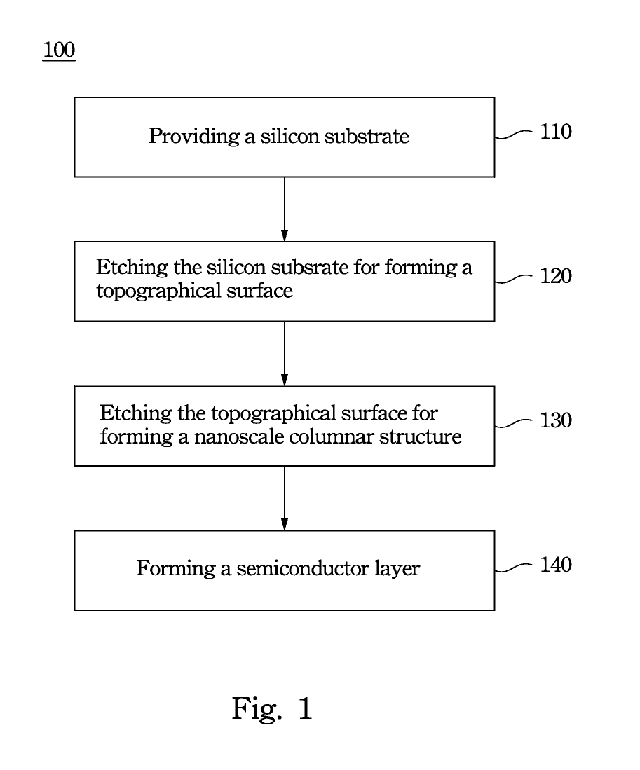

FIG. 1 is a flow chart of a method 100 for making an optical anti-reflection structure according to one embodiment of this disclosure. The method 100 of making the optical anti-reflection structure comprises the step 110 of providing a silicon substrate. In step 120, a concave-convex surface structure is formed on the silicon substrate surface by an etching process. Then in step 130, a nanoscale columnar structure is formed on the concave-convex surface for forming the anti-reflection structure by a metal-assist etching process. Later in step 140, a semiconductor layer is formed within the anti-reflection structure.

In one embodiment, the step 110 of the material of silicon substrate is selected from amorphous silicon, monocrystalline silicon, polycrystalline silicon and combinations thereof. The above step 120 of etching process comprises an isotropic etching process or an anisotropic etching process. According to one embodiment of this disclosure, the step 120 of using isotropic etching process is soaking the silicon substrate in an acid solution for forming the concave-convex surface on the surface of the silicon substrate. The acid solution is containing hydrofluoric acid (HF) or hydrofluoric-nitric-acetic (HNA) etching solution mixed by nitric acid (HNO₃) and acetic acid (CH₃COO). According to another embodiment of this disclosure, the step 120 of using anisotropic etching process is soaking the silicon substrate in an alkali solution for forming the concave-convex surface on the surface of the silicon substrate. The alkali solution is potassium hydroxide (KOH) or sodium hydroxide (NaOH).

According to one embodiment of this disclosure, the concave-convex surface structure is one selected from the group consisting of a pyramid structure, a strip groove structure, an irregularly coarsening structure and combinations thereof.

According to another embodiment, the above step 130 of the metal-assist etching process comprising performing oxidation on the silicon substrate by metal ions to produce silica. Then the nanoscale columnar structure is formed by wet etching process or dry etching process according to the embodiment of this disclosure. The metal ion is silver ion.

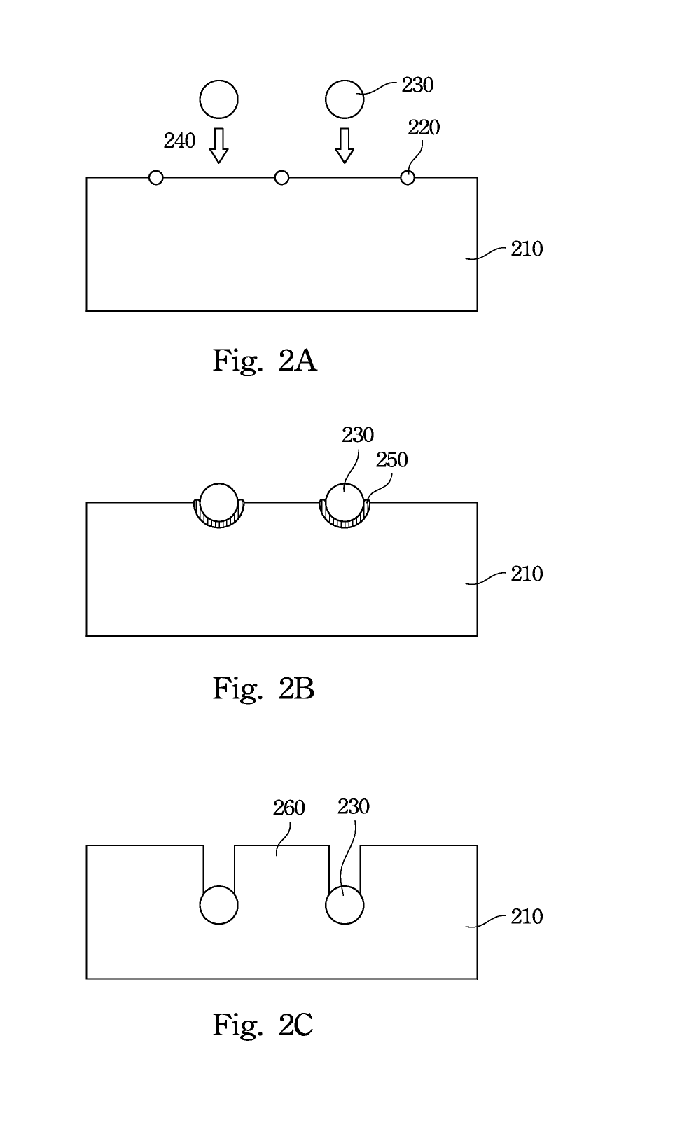

In one embodiment, an etching reaction is performed by a wet etching process. The process of the wet etching process is soaking a silicon substrate 210 in a solution containing silver ions 230, and the silver ions 230 carrying positive electricity move to the direction 240 of the silicon substrate 210 carrying negative electricity 220, as shown in FIG. 2A. The oxidation is performed by silver ions 230 and the silicon substrate 210, and the silicon oxide 250 is formed on the surface of the silicon substrate 210, as shown in FIG. 2B. Then hydrofluoric acid (HF) is added to react with silicon oxide (SiO₂) for producing soluble fluosilicic acid (H₂SiF₆), and thus performing the etching reaction for forming a nanoscale columnar structure 260, as shown in FIG. 2C. In another embodiment, a dry etching process performs an etching reaction by plasma.

In the other embodiment, the above step 140 of forming the semiconductor layer is a diffusion process or a deposition process. The diffusion process is doping a plurality of elements having five valence electrons into the anti-reflection structure for forming an N-type semiconductor layer, or doping a plurality of elements having three valence electrons into the anti-reflection structure for forming a P-type semiconductor layer. In the deposition process, an N-type semiconductor material is deposited on the anti-reflection structure to form the N-type semiconductor layer, or a P-type semiconductor material deposited on the anti-reflection structure to form the P-type semiconductor layer. According to one embodiment of this disclosure, the group VA-elements are phosphorous (P), arsenic (As) or antimony (Sb), and the group IIIA-elements are boron (B), aluminum (Al), gallium (Ga) or indium (In).

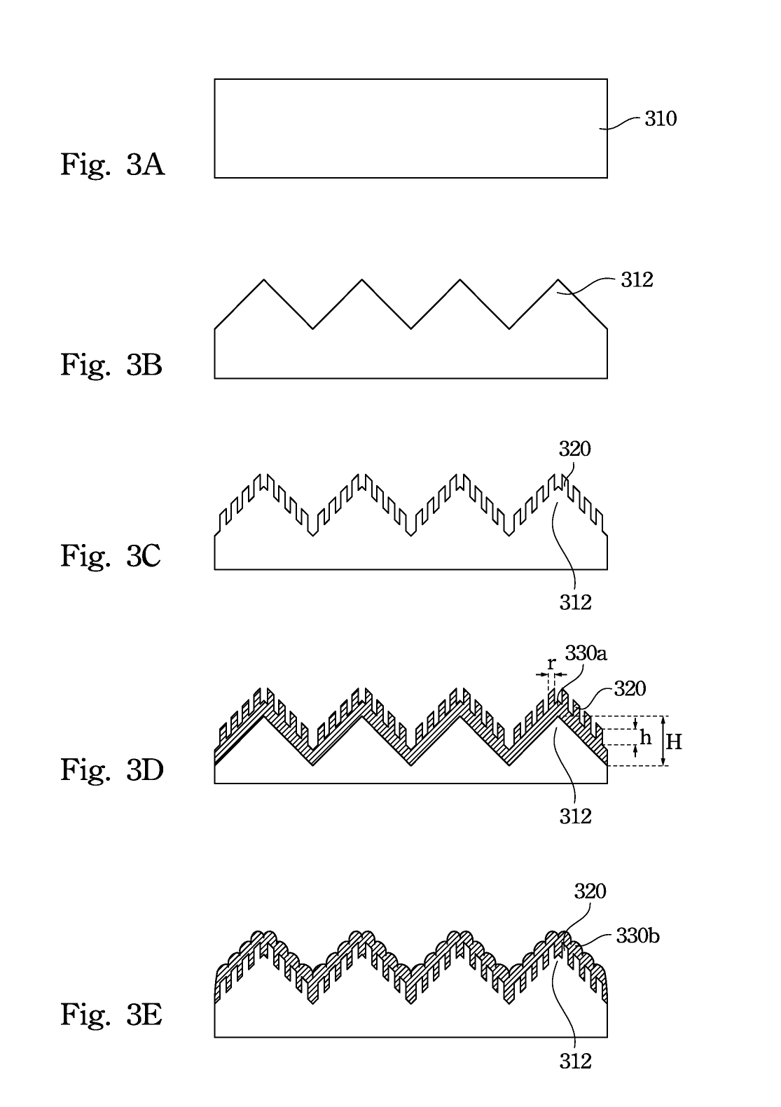

FIG. 3A to 3E are cross-sectional views illustrating the above process steps of the method 100 according to one embodiment of this disclosure. In one embodiment, a silicon substrate is provided, as shown in FIG. 3A. The silicon substrate 310 is etched by an anisotropic etching process to form a concave-convex structure 312 of a pyramid structure, as shown in FIG. 3B. Then the surface of the concave-convex structure 312 is etched by a wet etching process to form a nanoscale columnar structure 320, as shown in FIG. 3C. Doping a plurality of elements having five valence electrons into the anti-reflection structure by a diffusion process for forming a N-type semiconductor layer, as shown in FIG. 3D. In another embodiment, depositing a material of N-type semiconductor layer by a deposition process to form a N-type semiconductor layer, as shown in FIG. 3E. In yet another embodiment, the N-type semiconductor of FIGS. 3C and 3D can be replaced with a P-type semiconductor.

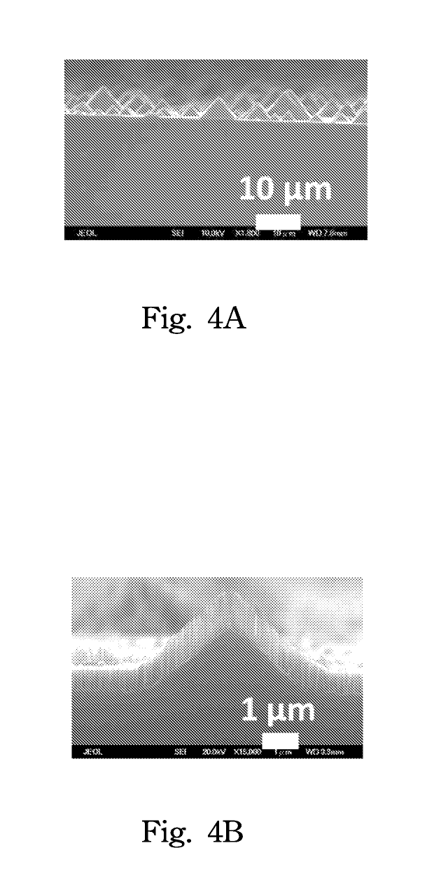

FIG. 4A is a scanning electron microscope images at 1800 times magnification of an optical anti-reflection structure according to one embodiment of this disclosure, and FIG. 4B is an scanning electron microscope images at 15000 times magnification of an optical anti-reflection structure according to one embodiment of this disclosure. As shown in FIG. 4A, the concave-convex surface structure of the antireflection structure comprises a plurality of pyramid groups with different sizes, and FIG. 4B further shows a portion of the nanoscale columnar structure on the concave-convex surface structure of the antireflection structure.

In one embodiment, refer to FIG. 3D, the ratio between the average peak-valley distance (H) of the concave-convex surface structure 310 and the height (h) of the nanoscale columnar structure 320 is 10 times to 100 times. The nanoscale columnar structure 320 has a plurality of nanoscale column having a height (h)/diameter (r) ratio of 10 to 100. The diameter (r) of the nanoscale columns is in the range of 20 to 50 nm.

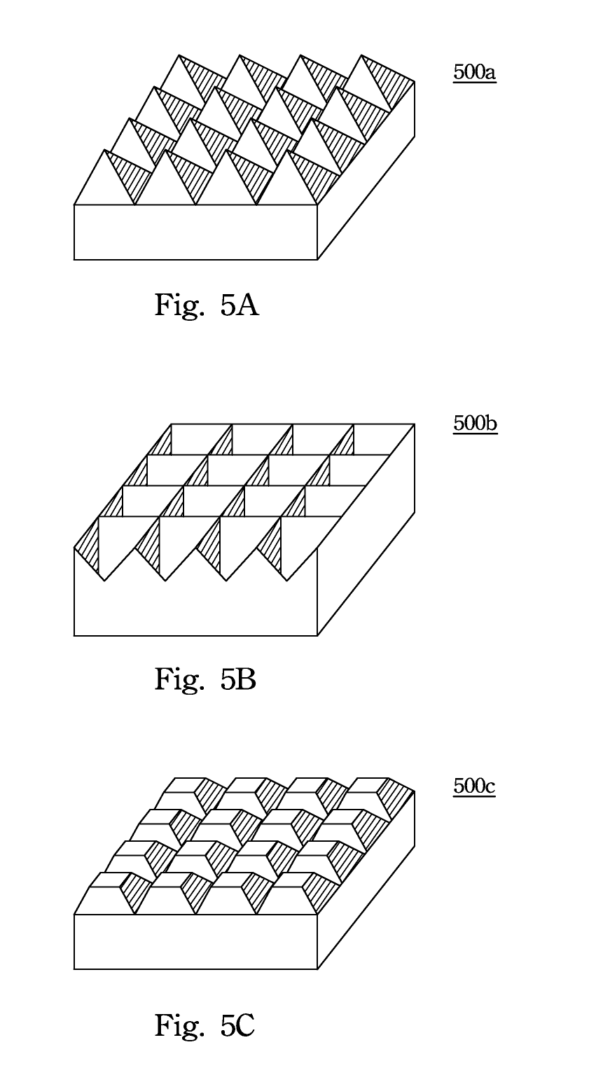

Refer to FIG. 5A to 5F, the pyramid structure in one embodiment of this disclosure is one selected from the group consisting of an upright pyramid structure 500a, an inverted pyramid structure 500b, a flat-topped pyramid structure 500c and combinations thereof. The strip groove structure is selected from a group consisting of a strip groove structure having triangle cross-section 500d a strip convex structure having trapezoidal cross-section 500e and combinations thereof. The irregularly coarsening structure 500f is shown as FIG. 5F.

According to one embodiment of the disclosure, the above pyramid structure comprises a plurality of pyramid groups with two or more different sizes. FIG. 4A is a scanning electron microscope images at 1800 times magnification. According to one embodiment of the disclosure, the pyramid groups with different sizes comprise a first pyramid group having a base width of 3 to 5 μm, a second pyramid group having a base width of 5 to 8 μm, and a third pyramid group having a base width of 8 to 10 μm.

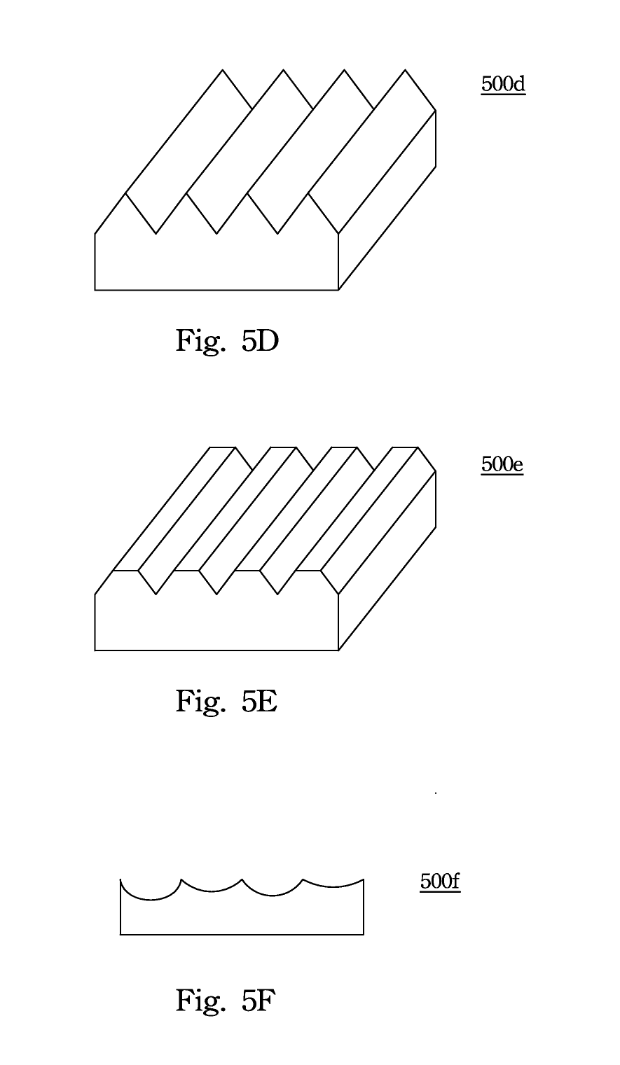

FIG. 6 is a graph of reflectivity of optical anti-reflection structures at different wavelengths. An anti-reflection structure as a comparative example has a concave-convex surface structure without a nanoscale columnar structure. An anti-reflection structure of the embodiment of this disclosure has a concave-convex surface structure and a nanoscale columnar structure. As shown in FIG. 6, at different wavelengths, reflectivity of the embodiment example is lower than the comparative example. The deviation of reflectivity is more expanded when the wavelength ranges from 300 to 1,100 nm. It shows that the disclosure of the anti-reflection structure having the nanoscale columnar structure can enhance reflectivity effectively.

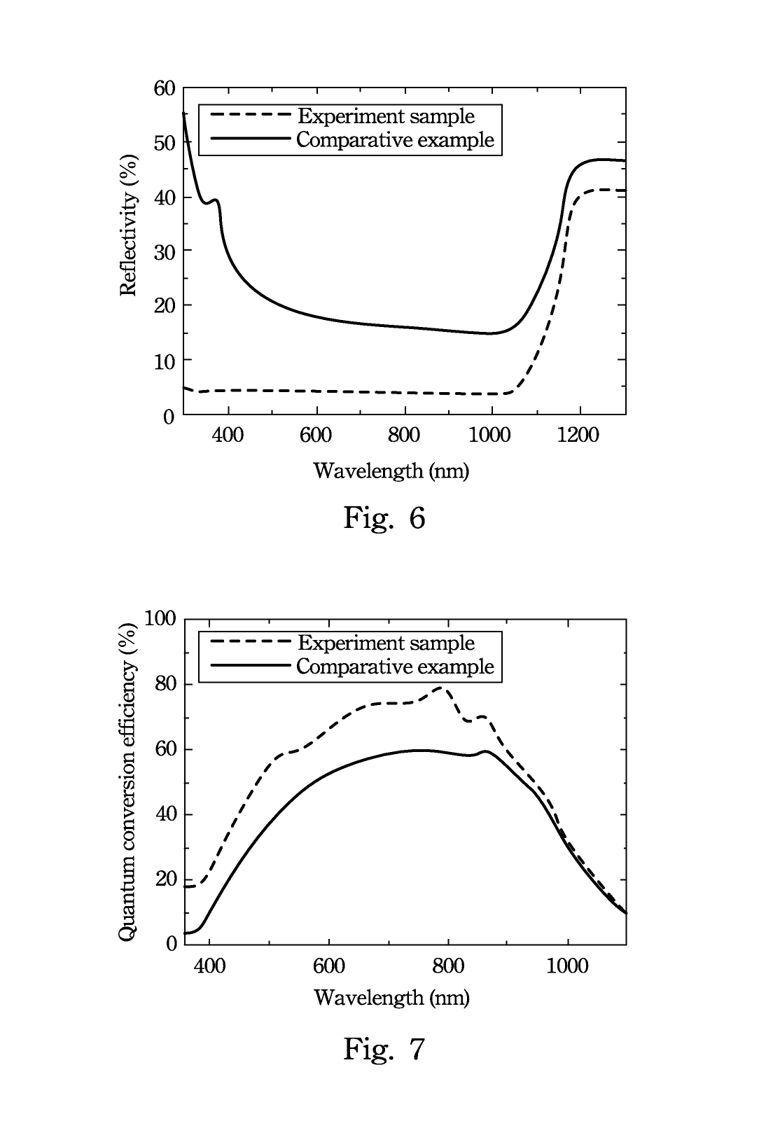

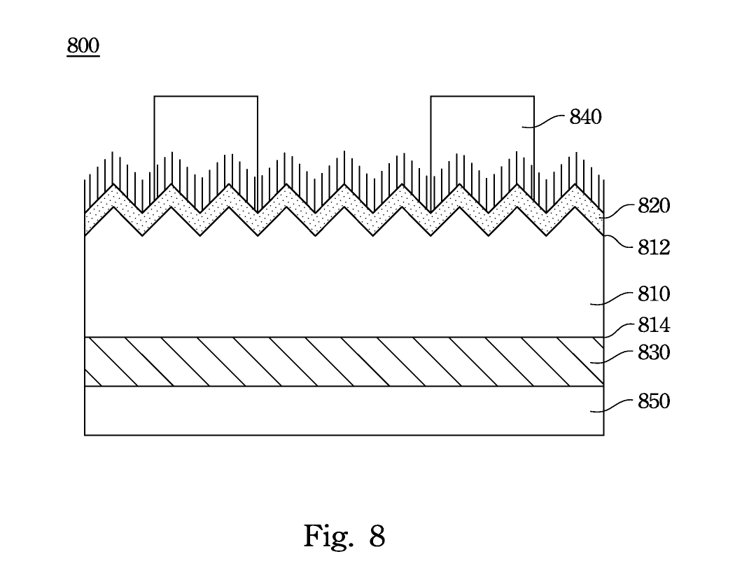

Refer to FIG. 8 and FIG. 7, FIG. 7 is a curve graph of quantum conversion efficiency of a solar cell at different wavelengths, and FIG. 8 is a cross-sectional view of a solar cell 800 according to one embodiment of this disclosure. As shown in FIG. 8, the solar cell comprises a photoelectric conversion layer 810, a first electrode 840 and a second electrode 850. The photoelectric conversion layer 810 has a first surface 812 and a second surface 814 opposite to the first surface 812, and the first surface 812 being a light incident plane has an anti-reflection structure as the above-mentioned. An N-type semiconductor layer is disposed on the first surface 812, and a P-type semiconductor layer is disposed on the second surface 814. The first electrode 840 is disposed on the first surface 812, and the second electrode 850 opposite to the first electrode 840 is disposed under the second surface 814.

FIG. 7 is a graph of quantum conversion efficiency of solar cells at different wavelengths based on the measurement results. In the graph, a solar cell as a comparative example has a concave-convex surface structure without a nanoscale columnar structure; in contrast, a solar cell according to the embodiment of this disclosure, which is shown in FIG. 8, has a concave-convex surface structure and a nanoscale columnar structure. From the analysis of the experimental results, the quantum conversion efficiency of the embodiment of this disclosure is higher than the comparative example by about 10 to 20%. It indicates that the nanoscale columnar structure can enhance the efficiency of anti-reflection, the rate of light absorption, and photocurrents.

Although the present disclosure has been described in considerable detail with reference to certain embodiments thereof, other embodiments are possible. Therefore, their spirit and scope of the appended claims should no be limited to the description of the embodiments container herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. An optical anti-reflection structure comprising:
a concave-convex surface structure; and
a nanoscale columnar structure on at least a portion of the concave-convex surface structure.

2. The optical anti-reflection structure of claim 1, wherein the ratio between an average peak-valley distance of the concave-convex surface structure and the height of the nanoscale columnar structure is 10 to 100.

3. The optical anti-reflection structure of claim 1, wherein the nanoscale columnar structure has a plurality of nanoscale columns with a height/diameter ratio of 10 to 100.

4. The optical anti-reflection structure of claim 3, wherein the diameter of the nanoscale columns is in the range of 20 to 50 nanometers (nm).

5. The optical anti-reflection structure of claim 1, wherein the concave-convex surface structure is one selected from the group consisting of a pyramid structure, a strip groove structure, an irregularly coarsening structure and combinations thereof.

6. The optical anti-reflection structure of claim 5, wherein the pyramid structure is one selected from the group consisting of an upright pyramid structure, an inverted pyramid structure, a flat-topped pyramid structure and combinations thereof.

7. The optical anti-reflection structure of claim 6, wherein the pyramid structure comprises a plurality of pyramid groups with different sizes.

8. The optical anti-reflection structure of claim 7, wherein the pyramid groups with different sizes comprise a first pyramid group having a base width of 3 to 5 micrometers (μm), a second pyramid group having a base width of 5 to 8 μm, and a third pyramid group having a base width of 8 to 10 μm.

9. A solar cell comprising:
a photoelectric conversion layer having a first surface and a second surface opposite to the first surface, wherein the first surface has the optical anti-reflection structure of claim 1;
a first electrode disposed on the first surface; and
a second electrode disposed under the second surface opposite to the first electrode.

10. A method for making an anti-reflection structure, comprising the steps of:
forming a concave-convex surface on a surface of a silicon substrate;
forming a nanoscale columnar structure on the concave-convex surface so as to form the anti-reflection structure; and
forming a semiconductor layer within the silicon substrate of the anti-reflection structure.

11. The method of claim 10, wherein the step of forming the concave-convex surface is an isotropic etching process or an anisotropic etching process.

12. The method of claim 11, wherein the isotropic etching process comprises a step of soaking the silicon substrate in an acid solution to form the concave-convex surface on the surface of the silicon substrate.

13. The method of claim 11, wherein the anisotropic etching process comprises a step of soaking the silicon substrate in an alkali solution to form the concave-convex surface on the surface of the silicon substrate.

14. The method of claim 10, wherein the step of forming the nanoscale columnar structure is by way of a metal-assist etching process.

15. The method of claim 14, wherein the metal-assisted etching process comprises a step of performing oxidation on the silicon substrate by metal ions to produce silica.

16. The method of claim 10, wherein the step of forming the semiconductor layer is by way of a diffusion process or a deposition process.

17. The method of claim 16, wherein the diffusion process comprises a step of doping a plurality of group VA-elements into the anti-reflection structure to form an N-type semiconductor layer, or doping a plurality of group IIIA-elements into the anti-reflection structure to form a P-type semiconductor layer.

18. The method of claim 16, wherein the deposition process comprises a step of depositing an N-type semiconductor material on the anti-reflection structure to form the N-type semiconductor layer, or depositing a P-type semiconductor material on the anti-reflection structure to form the P-type semiconductor layer.

19. The method of claim 17, wherein the group VA-elements are phosphorous (P), arsenic (As) or antimony (Sb), and the group IIIA-elements are boron (B), aluminum (Al), gallium (Ga) or indium (In).
